(19) United States
(12) Patent Application Publication
(10) Pub. No.: US 2015/0378194 A1
(43) Pub. Date: Dec. 31, 2015

(54) LIQUID CRYSTAL DISPLAY PANEL

(71) Applicant: SAMSUNG DISPLAY CO., LTD., Yongin-City (KR)

(72) Inventors: SEUNGHYUN PARK, Seoul (KR); HYANGYUL KIM, Hwaseong-si (KR); WOONGKI JEON, Yongin-Si (KR)

(21) Appl. No.: 14/686,451

(22) Filed: Apr. 14, 2015

(30) Foreign Application Priority Data
Jun. 26, 2014 (KR) 10-2014-0079071

(51) Int. Cl. G02F 1/1339; G02F 1/1337; G02F 1/1335; H01L 23/00; G02F 1/1368

(52) U.S. Cl. CPC G02F 1/1339; H01L 23/562; G02F 1/1368; G02F 1/133512; G02F 1/133514; G02F 1/1337; G02F 2001/13398; G02F 2001/13396

(57) ABSTRACT

A liquid crystal display panel includes a first substrate, a second substrate facing the first substrate, a plurality of first spacers disposed between the first and second substrates, and a plurality of second spacers disposed between the first and second substrates to maintain a cell gap between the first and second substrates in cooperation with the first spacers. Each first spacer includes a first sub-spacer integrally formed with the first substrate and a second sub-spacer disposed on the second substrate that overlaps the first sub-spacer.

### CROSS-REFERENCE TO RELATED APPLICATION

This U.S. non-provisional patent application claims priority under 35 U.S.C. §119 from Korean Patent Application No. 10-2014-0079071, filed on Jun. 26, 2014 in the Korean Intellectual Office, and all the benefits accruing therefrom, the contents of which are herein incorporated by reference in their entirety.

### BACKGROUND

1. Technical Field

Embodiments of the present disclosure are directed to a liquid crystal display panel. More particularly, embodiments of the present disclosure are directed to a liquid crystal display panel having improved display quality.

2. Discussion of the Related Art

A liquid crystal display includes a liquid crystal display panel, two polarizers, and a backlight unit to supply light to the liquid crystal display panel. The liquid crystal display panel includes two substrates and a liquid crystal layer interposed between the two substrates. The liquid crystal layer includes liquid crystal molecules.

The liquid crystal display panel includes spacers disposed between the two substrates. The spacers maintain a distance between the two substrates and absorb external impacts applied thereto.

### SUMMARY

Embodiments of the present disclosure provide a liquid crystal display panel capable of reducing light leakage and manufacturing costs thereof.

Embodiments of the inventive concept provide a liquid crystal display panel that includes a first substrate, a second substrate facing the first substrate, a plurality of first spacers disposed between the first and second substrates, and a plurality of second spacers disposed between the first and second substrates that maintain a cell gap between the first and second substrates in cooperation with the first spacer. Each first spacer includes a first sub-spacer integrally formed with the first substrate and a second sub-spacer disposed on the second substrate that overlaps the first sub-spacer.

Each second spacer includes a third sub-spacer integrally formed with the first substrate and spaced apart from the second substrate. The first sub-spacer may have substantially a same height as a height of the third sub-spacer.

The second spacer may further include a fourth sub-spacer that overlaps the third sub-spacer, is spaced apart from the third sub-spacer, and is disposed on the second substrate.

According to embodiments, the second spacer may include a third sub-spacer spaced apart from the first substrate and disposed on the second substrate. The second sub-spacer may have substantially a same height as a height of the third sub-spacer.

The second spacer may further include a fourth sub-spacer integrally formed with the first substrate, overlaps the third sub-spacer, and is spaced apart from the third sub-spacer.

According to embodiments, at least one of each of the first and second sub-spacers may have one of a cylindrical shape, a polygonal cylindrical shape, a truncated cone shape, or a polygonal cone shape. Each of the first and second sub-spacers respectively includes a first contact surface and a second contact surface in contact with each other.

The liquid crystal display panel further includes a liquid crystal layer interposed between the first substrate and the second substrate, a plurality of pixels disposed on the second substrate, and a plurality of signal lines. The liquid crystal display panel includes a plurality of pixel areas that respectively overlap the pixels and a peripheral area disposed adjacent to the pixel areas, and the signal lines are disposed on the second substrate overlap the peripheral area. The signal lines apply signals to the pixels. The first and second spacers are disposed in the peripheral area.

The liquid crystal display panel may further includes a plurality of color filters disposed on the second substrate that overlap the pixel areas, and a black matrix disposed on the second substrate that overlaps the peripheral area. The black matrix prevents light interference between adjacent pixel areas to each other among the pixel areas.

Each pixel includes a thin film transistor connected to a corresponding signal line, a pixel electrode connected to the thin film transistor that is provided with a plurality of slits defined therein, and a common electrode that overlaps the pixel electrode.

The liquid crystal display panel may further include an alignment layer disposed on the second substrate to cover the pixel electrode, and the second sub-spacer is disposed on the alignment layer.

Embodiments of the inventive concept provide a liquid crystal display panel that includes a first substrate, a second substrate facing the first substrate, a plurality of first spacers disposed between the first and second substrates to maintain a cell gap between the first and second substrates, and a plurality of second spacers disposed between the first and second substrates. Each second spacer comprises a third sub-spacer integrally formed with the first substrate. An arrangement of the second spacers is denser than an arrangement of the first spacers.

The second spacer may further comprises a fourth sub-spacer that overlaps the third sub-spacer, is spaced apart from the third sub-spacer, and is disposed on the second substrate.

Each first spacer comprises a first sub-spacer integrally formed with the first substrate and a second sub-spacer disposed on the second substrate that overlaps the first sub-spacer. The first and second sub-spacers respectively comprise a first contact surface and a second contact surface in contact with each other.

Embodiments of the inventive concept provide a liquid crystal display panel that includes a first substrate, a second substrate facing the first substrate, a plurality of first spacers disposed between the first and second substrates to maintain a cell gap between the first and second substrates, and a plurality of second spacers disposed between the first and second substrates. Each second spacer a fourth sub-spacer disposed on the second substrate that overlaps the first sub-spacer. An arrangement of the second spacers is denser than an arrangement of the first spacers.

The second spacer further comprises a fourth sub-spacer integrally formed with the first substrate that overlaps the third sub-spacer and is spaced apart from the third sub-spacer.

Each first spacer comprises a first sub-spacer integrally formed with the first substrate and a second sub-spacer disposed on the second substrate that overlaps the first sub-spacer. The first and second sub-spacers respectively comprise a first contact surface and a second contact surface in contact with each other.

### BRIEF DESCRIPTION OF THE DRAWINGS

FIG. 1 is a perspective view of a liquid crystal display panel according to an exemplary embodiment of the present disclosure.

FIG. 2 is a plan view of the liquid crystal display panel shown in FIG. 1.

FIG. 3 is a plan view of a pixel according to an exemplary embodiment of the present disclosure.

FIG. 4 is a cross-sectional view taken along a line I-I′ shown in FIG. 3.

FIG. 5 is a cross-sectional view taken along a line II-II′ shown in FIG. 3.

FIG. 6 is a cross-sectional view of a liquid crystal display panel according to an exemplary embodiment of the present disclosure.

FIGS. 7A to 7C are views of a method of manufacturing a sub-spacer according to an exemplary embodiment of the present disclosure.

FIGS. 8 to 11 are cross-sectional views of a liquid crystal display panel according to an exemplary embodiment of the present disclosure.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. Like numbers may refer to like elements throughout.

Hereinafter, exemplary embodiments of the present disclosure will be explained in detail with reference to the accompanying drawings.

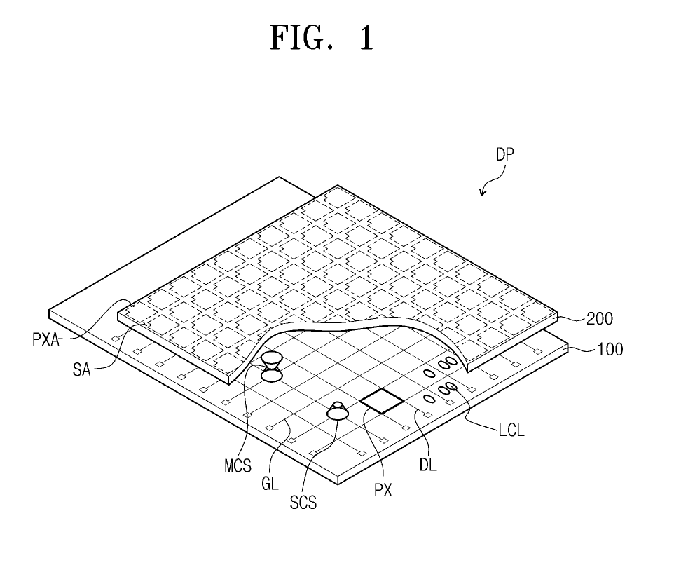

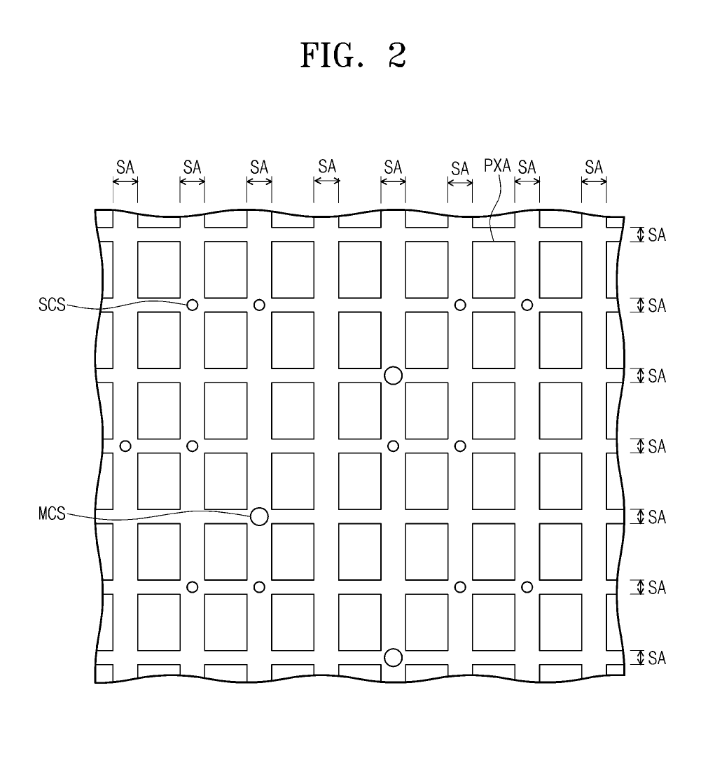

FIG. 1 is a perspective view of a liquid crystal display panel according to an exemplary embodiment of the present disclosure and FIG. 2 is a plan view of the liquid crystal display panel shown in FIG. 1. Hereinafter, a liquid crystal display panel DP will be described in detail with reference to FIGS. 1 and 2.

Referring to FIGS. 1 and 2, the liquid crystal display panel DP includes a first display substrate 100, a second display substrate 200 facing the first display substrate 100, a liquid crystal layer LCL interposed between the first and second display substrates 100 and 200, at least one first spacer MCS disposed between the first and second display substrates 100 and 200, and at least one second spacer SCS disposed between the first and second substrates 100 and 200. The liquid crystal display panel DP includes a plurality of pixel areas PXA and a peripheral area SA disposed between the pixel areas PXA when viewed in a plan view.

The first display substrate 100 includes a first base substrate (hereinafter, referred to as a first substrate), a plurality of insulating layers, and a plurality of conductive layers, which are disposed thereon. The conductive layers include a plurality of signal lines and a plurality of pixels PX. The signal lines overlap the peripheral area SA and the pixels PX overlap the pixel areas PXA when viewed in a plan view. The insulating layers are formed by coating and deposition processes. The pixels PX are formed by patterning the conductive layers using a photolithography process.

The signal lines include a plurality of gate lines GL and a plurality of data lines DL insulated from the gate lines GL that cross the gate lines GL. The gate lines GL receive gate signals and the data lines DL receive data voltages. Each pixel PX may be connected to one of the gate lines GL and one of the data lines DL. Each pixel PX includes a thin film transistor connected to the corresponding gate line and the corresponding data line and a liquid crystal capacitor connected to the thin film transistor.

The second substrate 200 includes a second base substrate (hereinafter, referred to as a second substrate) and a plurality of protrusion portions integrally formed therewith. The protrusion portions include the first spacer MCS and the second spacer SCS.

The first spacer MCS maintains a cell gap between the first and second display substrates 100 and 200. The first spacer MCS includes a sub-spacer disposed on the first display substrate 100 and a sub-spacer disposed on the second display substrate 200. The sub-spacer may have a cylindrical shape, a polygonal cylindrical shape, a truncated cone shape, or a polygonal cone shape.

The second spacer SCS maintains a cell gap decreased by an external pressure. Although the second display substrate 200 may be curved toward the first display substrate 100 by external pressure, a predetermined cell gap can be maintained by the second spacer SCS. The second spacer SCS includes at least one of the sub-spacer disposed on the first display substrate 100 and the sub-spacer disposed on the second display substrate 200. FIG. 1 shows the second spacer SCS as including the sub-spacer disposed on the first display substrate 100 as a representative example.

As shown in FIG. 2, the first and second spacers MCS and SCS may be disposed to overlap the peripheral area SA. A plurality of the first and second spacers MCS and SCS may be provided. The first spacers MCS are spaced apart from each other at regular intervals and the second spacers SCS are spaced apart from each other at regular intervals. An arrangement of the second spacers SCS is more dense than that of the first spacers MCS.

The liquid crystal display panel DP may be manufactured by preparing the first and second display substrates 100 and 200, coupling the first and second display substrates 100 and 200 such that the cell gap is defined therebetween, and injecting a liquid crystal material into the cell gap. As another way to manufacture the liquid crystal display panel DP, the liquid crystal material may be disposed on one of the first and second display substrates 100 and 200, and then the first display substrate 100 is coupled to the second display substrate 200 such that the liquid crystal material is disposed between the first and second display substrates 100 and 200.

The first and second spacers MCS and SCS may be formed when the first and second display substrates 100 and 200 are manufactured. Alternatively, the first and second spacers MCS and SCS may be formed on the first and second display substrates 100 and 200 after the first and second display substrates 100 and 200 are manufactured. That is, the first and second spacers MCS and SCS may be formed in various ways.

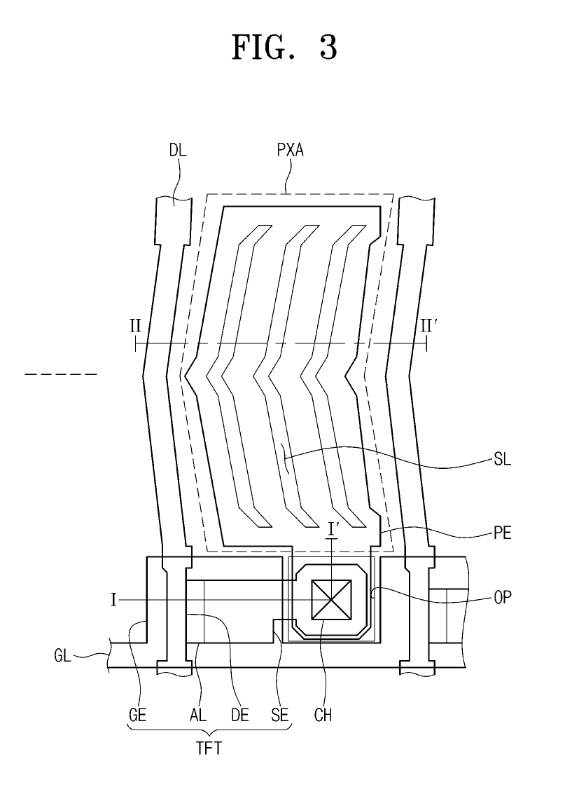

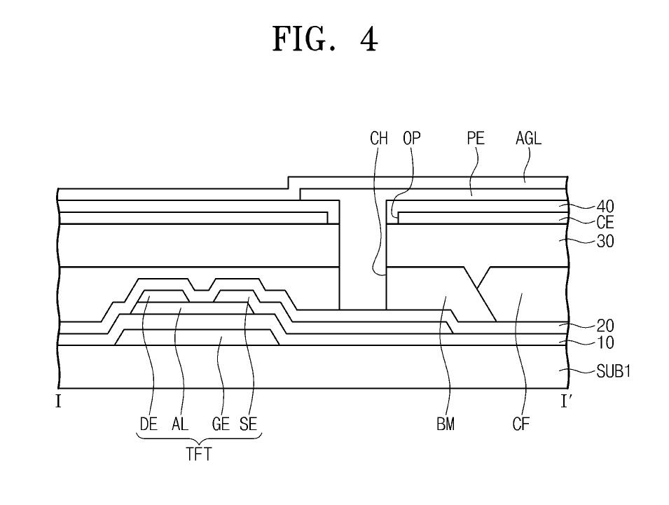

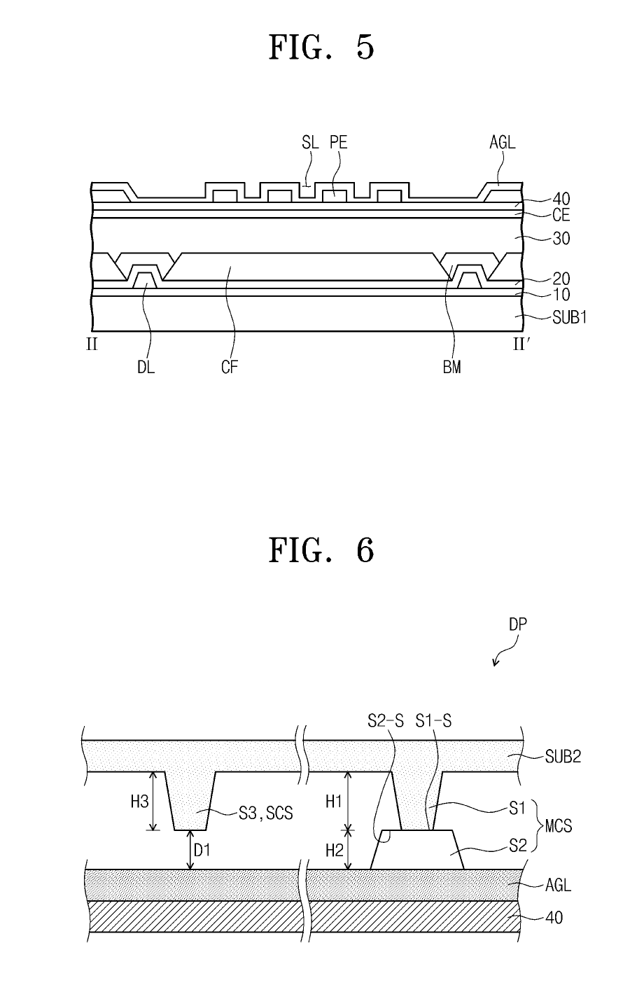

FIG. 3 is a plan view of a pixel according to an exemplary embodiment of the present disclosure, FIG. 4 is a cross-sectional view taken along a line I-I′ shown in FIG. 3, and FIG. 5 is a cross-sectional view taken along a line II-II′ shown in FIG. 3. Hereinafter, the pixel will be described in detail with reference to FIGS. 3 to 5.

In a present exemplary embodiment, a plane-to-line switching (PLS) mode pixel will be described in detail as a representative example, but a pixel is not limited thereto. That is, a liquid crystal display panel may include a vertical alignment (VA) mode, a patterned vertical alignment (PVA) mode, an in-plane switching mode, or a fringe-field mode pixel.

Referring to FIG. 4, the first display substrate 100 includes a first substrate SUB1, insulating layers 10, 20, 30, and 40, a color filter CF, a black matrix BM, and conductive layers. The conductive layers are used to form a gate line GL, a data line DL, a thin film transistor TFT, a common electrode CE, and a pixel electrode PE.

The first substrate SUB1 is a transparent substrate, such as a plastic substrate, a glass substrate, etc. The gate line GL and a control electrode GE of the thin film transistor TFT are disposed on one surface of the first substrate SUB 1. The gate line GL and the control electrode GE include a metal, such as aluminum (Ag), copper (Cu), molybdenum (Mo), chromium (Cr), tantalum (Ta), and titanium (Ti), etc., or alloys thereof. The gate line GL and the control electrode GE may have a single-layer structure or a multi-layer structure. In addition, a barrier layer and a buffer layer may be disposed on the surface of the first substrate SUB1.

A first insulating layer 10 is disposed on the first substrate SUB1 to cover the control electrode GE. The first insulating layer 10 includes at least one of a silicon nitride layer and a silicon oxide layer. A semiconductor layer AL is disposed on the first insulating layer 10. The semiconductor layer AL overlaps the control electrode GE such that the first insulating layer 10 is disposed between the semiconductor layer AL and the electrode layer GE. The semiconductor layer AL includes an active layer and an ohmic contact layer disposed on the active layer.

The data line DL, an input electrode DE, and an output electrode SE are disposed on the first insulating layer 10. The input electrode DE and the output electrode SE are spaced apart from each other. The input electrode DE and the output electrode SE overlap the semiconductor layer AL.

A second insulating layer 20 is disposed on the first insulating layer 10. The second insulating layer 20 includes at least one of a silicon nitride layer and a silicon oxide layer. The color filter CF and the black matrix BM are disposed on the second insulating layer 20. The color filter CF overlaps the pixel area PXA and the black matrix BM overlaps the peripheral area SA. In an alternative exemplary embodiment, the color filter CF and the black matrix BM may be disposed between the first insulating layer 10 and the first substrate SUB1.

A third insulating layer 30 is disposed on the color filter CF and the black matrix BM. The third insulating layer 30 provides a flat surface. The third insulating layer 30 includes an organic material. The common electrode CE is disposed on the third insulating layer 30. The common electrode CE is provided with an opening OP formed therethrough. The common electrode CE may overlap the pixel areas PXA. In other words, the common electrode corresponding to the pixels PX may be integrally formed as a single unitary and individual unit.

A fourth insulating layer 40 is disposed on the common electrode CE. The fourth insulating layer 40 may include an organic material or an inorganic material. The pixel electrode PE is disposed on the fourth insulating layer 40. The pixel electrode PE includes a plurality of slits SL. The pixel electrode PE is connected to the output electrode SE through a contact hole CH formed through the second, third, and fourth insulating layers 20, 30, and 40. The contact hole CH overlaps the opening OP. As shown in FIG. 4, the contact hole CH may be formed penetrating through the black matrix BM.

An insulating layer may be disposed on the fourth insulating layer 40 to cover the pixel electrode PE. As shown in FIGS. 4 and 5, an alignment layer AGL may be disposed on the fourth insulating layer 40. The liquid crystal layer LCL is horizontally aligned on the alignment layer AGL.

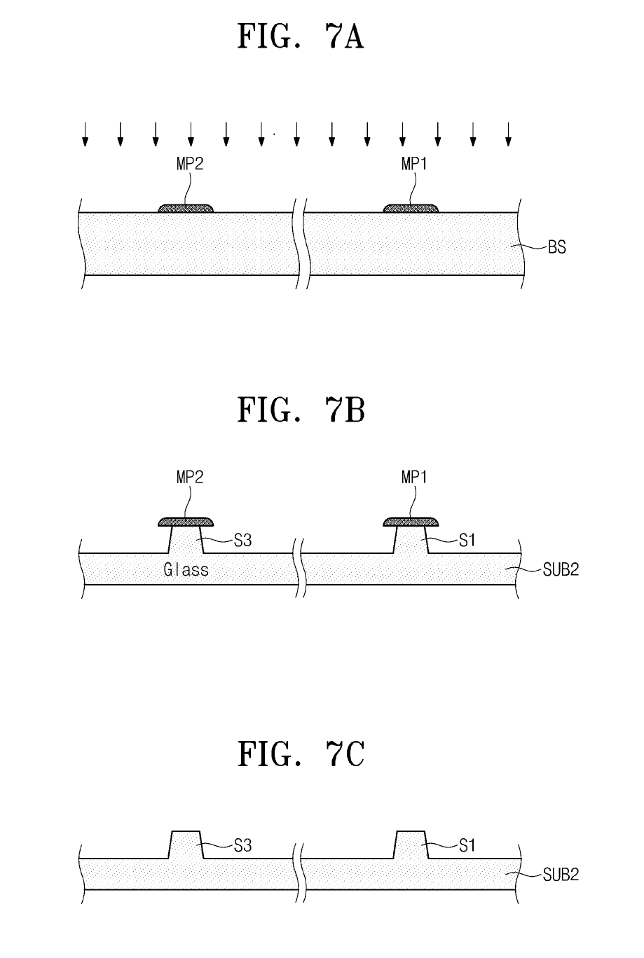

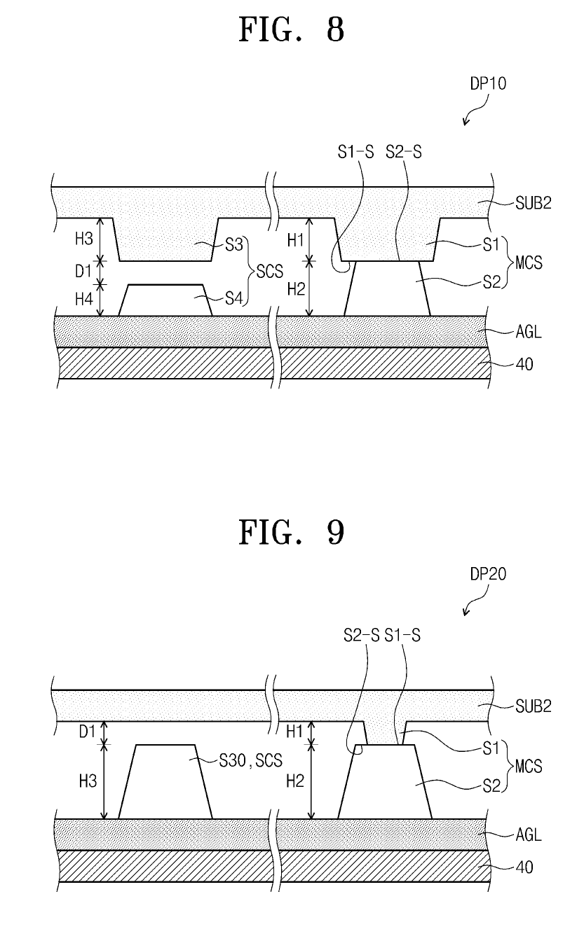

FIG. 6 is a cross-sectional view of a liquid crystal display panel according to an exemplary embodiment of the present disclosure and FIGS. 7A to 7C are views of a method of manufacturing a sub-spacer according to an exemplary embodiment of the present disclosure.

In FIG. 6, those elements of the first display substrate 100 disposed under the fourth insulating layer 40 are not shown. The first spacers MCS shown in FIG. 2 may be substantially the same as the first spacer MCS shown in FIG. 6 and the second spacer SCS shown in FIG. 2 may be substantially the same as the second spacer SCS shown in FIG. 6.

The first spacer MCS includes a first sub-spacer S1 integrally formed with the second substrate SUB2, and a second sub-spacer S2 disposed on the first substrate SUB1 to overlap the first sub-spacer S1. The second substrate SUB2 is a transparent substrate, such as a plastic substrate or a glass substrate. The first sub-spacer S1 may include glass or plastic.

Each of the first and second sub-spacers S1 and S2 may have a cylindrical shape, a polygonal cylindrical shape, a truncated cone shape, or a polygonal cone shape. The first sub-spacer S1 may have substantially the same shape as or a different shape from that of the second sub-spacer S2.

The first and second sub-spacers S1 and S2 respectively include a first contact surface S1-S and a second contact surface S2-S that make contact with each other. As described above, since the first and second sub-spacers S1 and S2 support to each other, a cell gap between the first and second display substrates 100 and 200 is maintained.

The second spacer SCS may include a third sub-spacer S3. The third sub-spacer S3 is integrally formed with the second substrate SUB2 and spaced apart from the first substrate SUB1. An alignment layer may be disposed on a lower surface of the second substrate SUB2 to cover the first and third sub-spacers S1 and S3. Alternatively, the alignment layer disposed on the lower surface of the second substrate SUB2 may not cover the first and third sub-spacers S1 and S3.

The first and third sub-spacers S1 and S3 have substantially the same heights H1 and H3. This is because the first and third sub-spacers S1 and S3 are formed from a glass substrate or a plastic substrate through the same process. Hereinafter, a method of manufacturing the first and third sub-spacers S1 and S3 will be described in detail with reference to FIGS. 7A to 7C.

Referring to FIG. 7A, mask patterns MP1 and MP2 are formed on a base substrate BS. The first and third sub-spacers S1 and S3 may be formed to have substantially the same shape according to a size and a shape of the mask patterns MP1 and MP2. The mask patterns MP1 and MP2 are formed by forming a photoresist layer on the base substrate BS using a coating method, irradiating light onto portions of the photoresist layer, and developing the irradiated portions of the photoresist layer.

As shown in FIG. 7A, the base substrate BS is partially etched using the mask patterns MP1 and MP2. The base substrate BS may be etched by a dry etching method that uses an etching gas containing tetrafluoromethane (CF₄), hydrogen, and argon. In this case, a glass substrate may be used as the base substrate BS so that the base substrate BS may be uniformly patterned. According to embodiments, the base substrate BS may also be etched by a wet etching method.

Referring to FIG. 7B, the etched base substrate BS is ached. Therefore, the protrusions S1 and S3 may be formed on the base substrate BS. The protrusions S1 and S3 correspond to the first and third sub-spacers S1 and S3 shown in FIG. 6, respectively.

Referring to FIG. 7C, the mask patterns MP1 and MP2 may be removed. Thus, the second substrate SUB2 shown in FIG. 6 may be manufactured. In addition, an alignment layer may be further formed on the base substrate BS to cover the protrusions. Alternatively, the alignment layer may not cover the protrusions.

Hereinafter, the first and second spacers MCS and SCS will be described in detail with reference to FIG. 6.

The second sub-spacer S2 may be disposed on the alignment layer AGL. The second sub-spacer S2 may include an organic material or an inorganic material. The inorganic material includes at least one of silicon nitride and silicon oxide. The second sub-spacer S2 may have a double-layer structure of a silicon nitride layer and a silicon oxide layer.

The second sub-spacer S2 may be formed by forming an organic layer or an inorganic layer on the alignment layer AGL and patterning the layer. Only one type of the second sub-spacer S2 is disposed on the alignment layer AGL. Accordingly, the second sub-spacer S2 may be formed on the alignment layer AGL through a single patterning process without using a halftone mask. Therefore, the manufacturing process may be simplified and the manufacturing cost may be reduced.

In a present exemplary embodiment, the second sub-spacer S2 may be disposed on the fourth insulating layer 40. After the second sub-spacer S2 is formed on the fourth insulating layer 40, the alignment layer AGL is formed on the fourth insulating layer 40. In this case, the alignment layer AGL may cover the second sub-spacer S2.

The height H2 of the second sub-spacer S2 may be substantially the same as a distance D1 between the third sub-spacer S3 and the alignment layer AGL. The cell gap in the portion in which the third sub-spacer S3 is disposed may decrease by up to the distance D1 due to an external pressure. The second display substrate 200 may be curved toward the first display substrate 100 due to the application of external pressure to the portion that overlaps the third sub-spacer S3, and the cell gap in the portion that overlaps the third sub-spacer S3 may decrease to a value that corresponds to the height H3 of third sub-spacer S3.

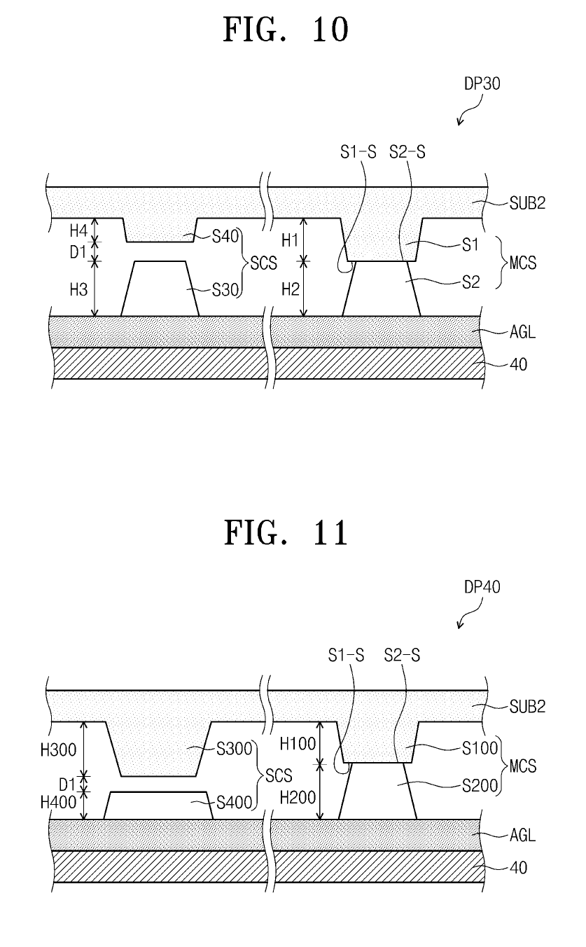

FIG. 8 is a cross-sectional view of a liquid crystal display panel DP10 according to an exemplary embodiment of the present disclosure. In FIG. 8, the same reference numerals may denote the same elements as in FIGS. 1 to 7C, and thus detailed descriptions of the same elements will be omitted.

Referring to FIG. 8, the liquid crystal display panel DP10 includes a first spacer MCS and a second spacer SCS. The first spacer MCS includes a first sub-spacer S1 and a second sub-spacer S2 and the second spacer SCS includes a third sub-spacer S3 and a fourth sub-spacer S4. The first and third sub-spacers S1 and S3 have substantially the same heights H1 and H3.

The second spacer SCS shown in FIG. 8 further includes a fourth sub-spacer S4 as compared to the second spacer SCS shown in FIG. 7. The fourth sub-spacer S4 may have a cylindrical shape, a polygonal cylindrical shape, a truncated cone shape, or a polygonal cone shape. The fourth sub-spacer S4 may be disposed on the same layer as the second sub-spacer S2 and may include the same material as the second sub-spacer S2. The fourth sub-spacer S4 has a height H4 less than the height H2 of the second sub-spacer S2. The fourth sub-spacer S4 and the second sub-spacer S2 may have a different layer structure. The fourth sub-spacer S4 and the third sub-spacer S3 may be spaced apart from each other by a predetermined distance D1.

A cell gap in the portion in which the second spacer SCS is disposed may decrease by up to the distance D1 due to an external pressure. The second display substrate 200 may be curved toward the first display substrate 100 by the application of external pressure to the portion that overlaps the second spacer SCS, however, a cell gap in that portion may be maintained.

When the second display substrate 200 is curved, the third sub-spacer S3 does not make contact with the alignment layer AGL disposed in the vicinity of the fourth sub-spacer S4. This is because the fourth sub-spacer S4 supports the third sub-spacer S3. The alignment layer AGL may not be damaged by the third sub-spacer S3. Therefore, light leakage may be prevented from occurring in the vicinity of the second spacer SCS.

FIG. 9 is a cross-sectional view of a liquid crystal display panel DP20 according to an exemplary embodiment of the present disclosure. In FIG. 9, the same reference numerals may denote the same elements as in FIGS. 1 to 8, and thus detailed descriptions of the same elements will be omitted.

Referring to FIG. 9, the liquid crystal display panel DP20 includes a first spacer MCS and a second spacer SCS. The first spacer MCS includes a first sub-spacer S1 and a second sub-spacer S2, and the second spacer SCS includes a third sub-spacer S30.

The third sub-spacer S30 may be disposed on the first substrate SUB1. The first sub-spacer S1 has a height H1 that is substantially the same as a distance D1 between the third sub-spacer S30 and the second substrate SUB2.

The third sub-spacer S30 has a height H3 that is substantially the same as a height H2 of the second sub-spacer S2. The third sub-spacer S30 may be disposed on the same layer as the second sub-spacer S2 and may include the same material as the second sub-spacer S2. The third sub-spacer S30 and the second sub-spacer S2 may have the same layer structure. The third sub-spacer S30 and the second sub-spacer S2 may be formed on the alignment layer AGL through a single patterning process without using a halftone mask. Thus, the manufacturing process may be simplified and the manufacturing cost may be reduced.

A cell gap in the portion in which the third sub-spacer S30 is disposed may be decreased by up to the distance D1 due to an external pressure. The second display substrate 200 may be curved toward the first display substrate 100 by the application of external pressure to the portion that overlaps the third sub-spacer S30, however, the cell gap in that portion may have a value corresponding to at least the height H3 of the third sub-spacer S30.

FIG. 10 is a cross-sectional view of a liquid crystal display panel DP30 according to an exemplary embodiment of the present disclosure. In FIG. 10, the same reference numerals may denote the same elements in FIGS. 1 to 9, and thus detailed descriptions of the same elements will be omitted.

Referring to FIG. 10, the liquid crystal display panel DP30 includes a first spacer MCS and a second spacer SCS. The first spacer MCS includes a first sub-spacer S1 and a second sub-spacer S2 and the second spacer SCS includes a third sub-spacer S3 and a fourth sub-spacer S40. The second sub-spacer S2 and the third sub-spacer S30 have substantially the same height H2 and H30.

The second spacer SCS shown in FIG. 10 further includes the fourth sub-spacer S40 as compared to the second spacer SCS shown in FIG. 9. The fourth sub-spacer S40 may have a cylindrical shape, a polygonal cylindrical shape, a truncated cone shape, or a polygonal cone shape. The fourth sub-spacer S40 may be integrally formed with the second substrate SUB2.

The fourth sub-spacer S40 has a height H4 less than a height H1 of the first sub-spacer S1. The fourth sub-spacer S40 may be spaced apart from the third sub-spacer S30 by a distance D1. As shown in FIG. 7B, after the base substrate with the protrusions S1 and S3 is formed, one mask pattern MP2 of the mask patterns MP1 and MP2 is removed. Then, a second etching process and a second ashing process are performed to adjust a height of one of the protrusions S1 and S3. Accordingly, the second substrate SUB2, on which the fourth sub-spacer S40 and the first sub-spacer S1 are disposed, is manufactured.

The second display substrate 200 may be curved toward the first display substrate 100 by the application of external pressure to the portion that overlaps the second spacer SCS, however, a predetermined cell gap may be maintained in the portion that overlaps the second spacer SCS. When the second display substrate 200 is curved, the fourth sub-spacer S40 is prevented from making contact with the alignment layer AGL disposed in the vicinity of the third sub-spacer S30. That is, the alignment layer AGL may not be damaged by the fourth sub-spacer S40. Therefore, light leakage may be prevented from occurring in the vicinity of the second spacer SCS.

FIG. 11 is a cross-sectional view of a liquid crystal display panel DP40 according to an exemplary embodiment of the present disclosure. In FIG. 11, the same reference numerals may denote the same elements in FIGS. 1 to 10, and thus detailed descriptions of the same elements will be omitted.

Referring to FIG. 11, the liquid crystal display panel DP40 includes a first spacer MCS and a second spacer SCS. The first spacer MCS includes a first sub-spacer S100 and a second spacer S200 and the second spacer SCS includes a third sub-spacer S300 and a fourth sub-spacer S400.

The first and third sub-spacers S100 and S300 may be integrally formed with the second substrate SUB2 as a single unitary and individual unit. The first and third sub-spacers S100 and S300 may have different heights H100 and H300.

The second and fourth sub-spacers S200 and S400 may be disposed on the same layer and may include the same material. The second and fourth sub-spacers S200 and S400 may have different heights H200 and H400. The second and fourth sub-spacers S200 and S400 may have different layer structures.

The first and second sub-spacers S100 and S200 may make contact with each other and the third and fourth sub-spacers S300 and S400 may be spaced apart from each other by a predetermined distance D1. The second display substrate 200 may be curved toward the first display substrate 100 by the application of an external pressure to the portion that overlaps the second spacer SCS, however, a predetermined cell gap may be maintained in the overlapped portion.

According to the above, the first spacer may maintain the cell gap between the first substrate and the second substrate. The second spacer may maintain a cell gap decreased by external pressure. The second spacer prevents the first substrate from making contact with the second substrate.

In addition, some sub-spacers disposed on the second substrate have the same height. Other sub-spacers are disposed on the first substrate. The first spacer includes two sub-spacers disposed on the first and second substrates. The second spacer may include one sub-spacer disposed on the first substrate or the second substrate. Those sub-spacers having the same height may reduce the manufacturing cost and time of a liquid crystal display panel.

Further, the two overlapping sub-spacers may prevent the alignment layer from being damaged even when the liquid crystal display panel is deformed. The two sub-spacers do not make contact with the alignment layer since the two sub-spacers support each other when the cell gap is decreased. Thus, light leakage may be prevented from occurring due to the spacer.

Although exemplary embodiments of the present disclosure have been described, it is understood that embodiments of the present disclosure should not be limited to these exemplary embodiments but that various changes and modifications can be made by one of ordinary skill in the art within the spirit and scope of embodiments of the present disclosure as hereinafter claimed.

What is claimed is:

1. A liquid crystal display panel comprising:
a first substrate;
a second substrate facing the first substrate;
a plurality of first spacers disposed between the first and second substrates that maintain a cell gap between the first and second substrates; and
a plurality of second spacers disposed between the first and second substrates,
wherein each first spacer comprises a first sub-spacer integrally formed with the first substrate and a second sub-spacer disposed on the second substrate that overlaps the first sub-spacer.

2. The liquid crystal display panel of claim 1, wherein each second spacer comprises a third sub-spacer integrally formed with the first substrate and spaced apart from the second substrate.

3. The liquid crystal display panel of claim 2, wherein the third sub-spacer has substantially a same height as a height of the first sub-spacer.

4. The liquid crystal display panel of claim 2, wherein the second spacer further comprises a fourth sub-spacer that overlaps the third sub-spacer, is spaced apart from the third sub-spacer, and is disposed on the second substrate.

5. The liquid crystal display panel of claim 1, wherein each second spacer comprises a third sub-spacer spaced apart from the first substrate and disposed on the second substrate.

6. The liquid crystal display panel of claim 5, wherein the third sub-spacer has substantially a same height as a height of the second sub-spacer.

7. The liquid crystal display panel of claim 6, wherein the second spacer further comprises a fourth sub-spacer integrally formed with the first substrate that overlaps the third sub-spacer and is spaced apart from the third sub-spacer.

8. The liquid crystal display panel of claim 1, wherein at least one of each of the first and second sub-spacers has one of a cylindrical shape, a polygonal cylindrical shape, a truncated cone shape, or a polygonal cone shape.

9. The liquid crystal display panel of claim 1, wherein each of the first and second sub-spacers respectively comprises a first contact surface and a second contact surface in contact with each other.

10. The liquid crystal display panel of claim 1, further comprising:
a liquid crystal layer interposed between the first substrate and the second substrate;
a plurality of pixels disposed on the second substrate; and
a plurality of signal lines,
wherein the liquid crystal display panel comprises a plurality of pixel areas that respectively overlap the pixels and a peripheral area disposed adjacent to the pixel areas, the signal lines are disposed on the second substrate and overlap the peripheral area and apply signals to the pixels, and the first and second spacers are disposed in the peripheral area.

11. The liquid crystal display panel of claim 10, further comprising a plurality of color filters disposed on the second substrate that overlap the pixel areas, and a black matrix disposed on the second substrate that overlaps the peripheral area and prevents light interference between adjacent pixel areas.

12. The liquid crystal display panel of claim 10, wherein each pixel comprises:
a thin film transistor connected to a corresponding signal line;
a pixel electrode connected to the thin film transistor that is provided with a plurality of slits defined therein; and
a common electrode that overlaps the pixel electrode.

13. The liquid crystal display panel of claim 12, further comprising an alignment layer disposed on the second substrate to cover the pixel electrode, wherein the second sub-spacer is disposed on the alignment layer.

14. The liquid crystal display panel of claim 1, wherein an arrangement of the second spacers is denser than an arrangement of the first spacers.

15. A liquid crystal display panel comprising:
a first substrate;
a second substrate facing the first substrate;
a plurality of first spacers disposed between the first and second substrates to maintain a cell gap between the first and second substrates; and
a plurality of second spacers disposed between the first and second substrates,
wherein each second spacer comprises a third sub-spacer integrally formed with the first substrate, and an arrangement of the second spacers is denser than an arrangement of the first spacers.

16. The liquid crystal display panel of claim 15, wherein the second spacer further comprises a fourth sub-spacer that overlaps the third sub-spacer, is spaced apart from the third sub-spacer, and is disposed on the second substrate.

17. The liquid crystal display panel of claim 16, wherein each first spacer comprises a first sub-spacer integrally formed with the first substrate and a second sub-spacer disposed on the second substrate that overlaps the first sub-spacer, and wherein the first and second sub-spacers respectively comprise a first contact surface and a second contact surface in contact with each other.

18. A liquid crystal display panel comprising:
a first substrate;
a second substrate facing the first substrate;
a plurality of first spacers disposed between the first and second substrates to maintain a cell gap between the first and second substrates; and
a plurality of second spacers disposed between the first and second substrates,
wherein each second spacer a fourth sub-spacer disposed on the second substrate that overlaps the first sub-spacer, and an arrangement of the second spacers is denser than an arrangement of the first spacers.

19. The liquid crystal display panel of claim 18, wherein the second spacer further comprises a fourth sub-spacer integrally formed with the first substrate that overlaps the third sub-spacer and is spaced apart from the third sub-spacer.

20. The liquid crystal display panel of claim 19, wherein each first spacer comprises a first sub-spacer integrally formed with the first substrate and a second sub-spacer disposed on the second substrate that overlaps the first sub-spacer, and wherein the first and second sub-spacers respectively comprise a first contact surface and a second contact surface in contact with each other.
